(19) United States
(12) Patent Application Publication
(10) Pub. No.: US 2004/0233633 A1
(43) Pub. Date: Nov. 25, 2004

(54) Structures for coolers with two-way air convection functionality

(76) Inventor: Mei-Ying Lay, Taoyuan (TW)

Correspondence Address: TROXELL LAW OFFICE PLLC, Suite 1404, 5205 Leesburg Pike, Falls Church, VA, 22041, US

(21) Appl. No.: 10/443,833

(22) Filed: May 23, 2003

(51) Int. Cl. H05K 7/20

(52) U.S. Cl. 361/697

(57) ABSTRACT

The present invention relates to a cooler with two-way air convection functionality consists of a base, an upper cover and a fan, wherein the upper cover is fastened to the base, forming an opening on both sides of the base for air convection. Inside the base there is a fan. There is a blocking board at the openings formed by the base and the upper cover, on either side of said fan, diverging air inside said base into two streams, with one stream inhaled from said opening and the other exhausted from the other opening through said rotating fan. There is an air guide path inside the base that reduces the space for air convection and enhances the amount of air inhaled and exhausted, thus dissipates heat within.

### FIELD OF THE INVENTION

The present invention relates to a cooler for PC, electronic devices and communication appliances, capable of changing air convection to bi-directional and curviform convection.

### BACKGROUND OF THE INVENTION

Traditional coolers only performs one-way and vertical-style air convection as up-and-down and back-and-forth. These techniques have been widely used in coolers.

### SUMMARY OF THE INVENTION

The main objective for the present invention is to provide a cooler with two-way air convention functionality, enhancing heat dissipation efficiency for traditional coolers. Two-way air convection enlarges its coverage while breaks the limitation of direction found in traditional coolers.

The present invention features in the cooler structure able to provide two-way air convection, wherein the curviform design allowing the air inhaled and exhausted to interact and generate air convection.

In the following, the embodiment illustrated is used to describe the detailed structural characteristics and operation action for the present invention.

### BRIEF DESCRIPTION OF THE DRAWINGS

FIG. 1 is a three-dimensional illustration for the appearances of the present invention.

FIG. 2 is a three-dimensional illustration for deformation of the present invention.

FIG. 3 is an illustration for the application of the present invention.

FIG. 4 is an illustration for another application of the present invention.

FIG. 5 is an illustration for the application on a notebook of the present invention.

FIG. 6 is an illustration for the application on a CPU of the present invention.

### DETAILED DESCRIPTION OF THE INVENTION

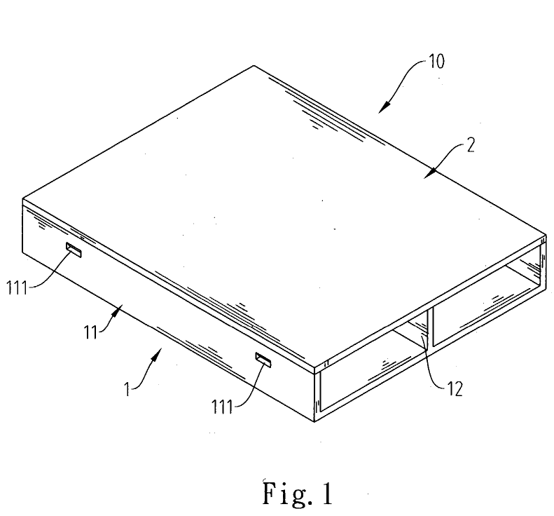

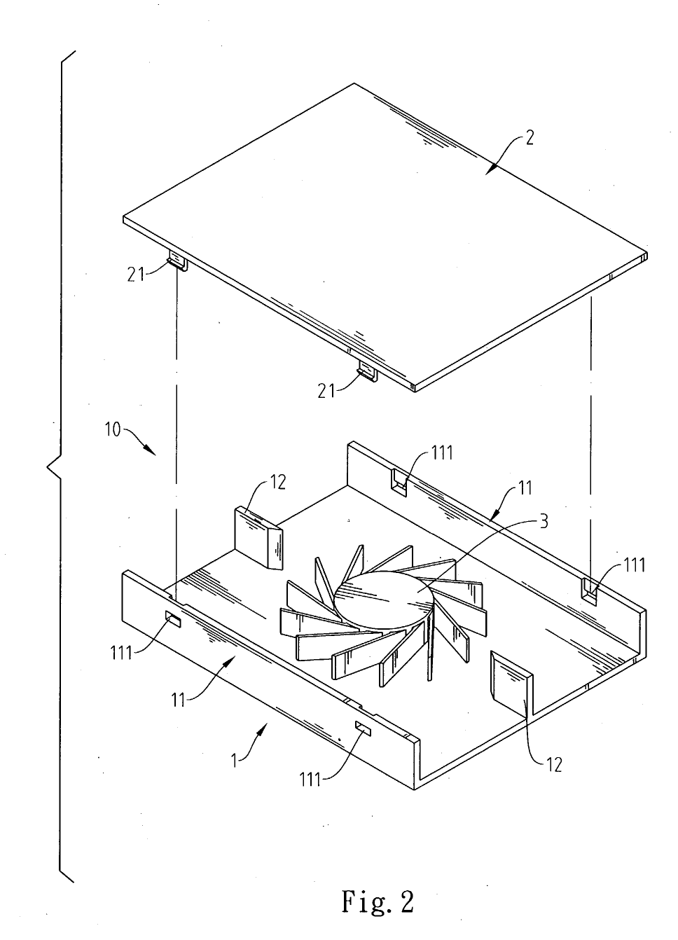

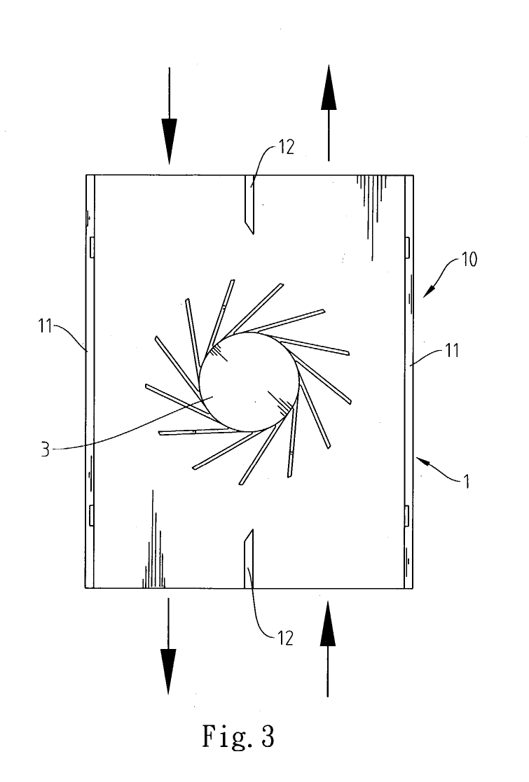

Please refer to FIG. 1 to FIG. 3. The cooler with two-way air convection functionality consists of a base 1, an upper cover 2 and a cooler 3, wherein the tenon 21 of the upper cover 2 is fastened to the buttonhole 111 of the side plate 11 of the base 1, forming into an opening on both sides of the base 1 for air convection. Inside the base 1 there is a fan 3.

There is a blocking board 12 at the openings above, on both side of the fan 3. Inside the blocking board 12 there is a bevel for guiding the air. The blocking board 12 diverges the air inside the base 1 into two streams, with one stream inhaled from the opening and the other exhausted from the opening through the rotating fan 3.

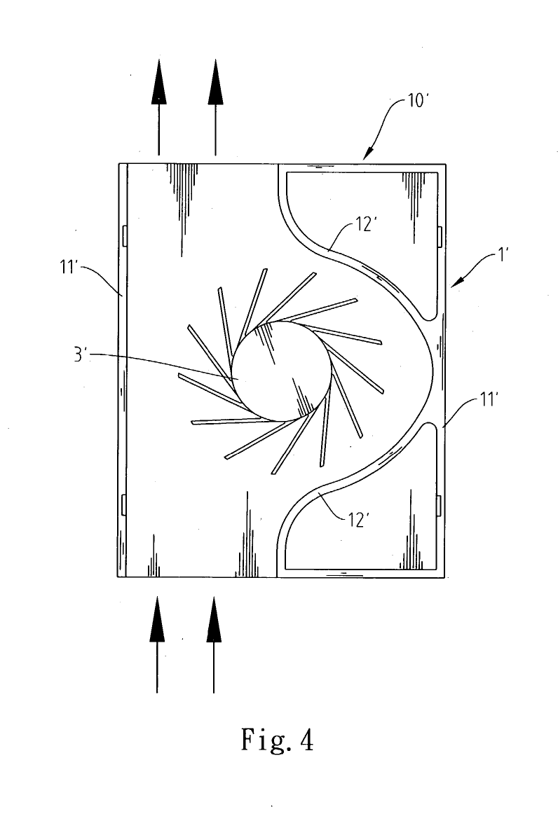

Please refer to FIG. 4. The cooler for the present invention 10′ contains a base 1′, an upper cover 2′ and a fan 3′, wherein the upper cover 2′ is fastened to the base 1′, forming into an opening on both sides of the base 1′ for air convection. Inside the base 1′ there is a fan 3′.

On one of the side board 11′ of the base 1′ there is an curviform air guide path 12′, placed on one side of the fan 3′, forming a narrow air convection guide path inside the base 1′.

Through the rotation of the fan 3′, the air is inhaled and exhausted from the base 1′ in single direction. The air guide path 12′ inside the base 1′ reduces the space for air convection, enhancing the amount of air inhaled and exhausted, thus dissipates the heat within. The present invention can also be applied to different situations to provide excellent cooling effects.

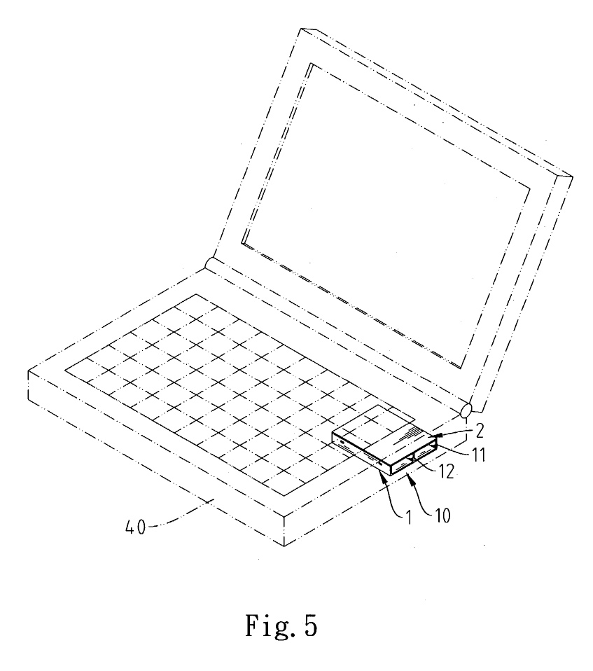

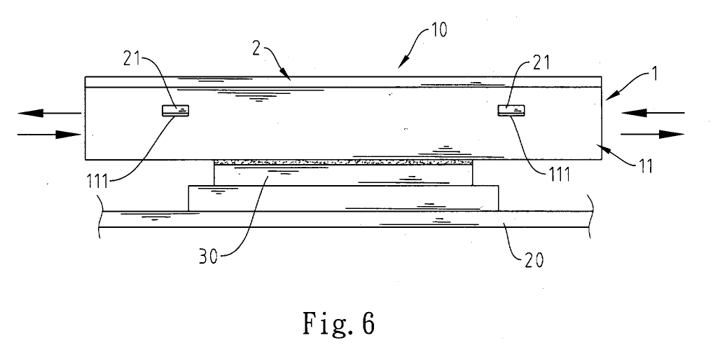

Please refer to FIG. 5 and FIG. 6. The cooler with two-way air convection functionality can be used in a notebook 40 for heat dissipation. The cooler 10 (or cooler 10′) can be fastened on top of the CPU 30, reducing the temperature of the CPU 30. Since the CPU 30 is usually placed on the side within the notebook 40, the cooler 10 can generate air convection with external air, thus cools down the CPU's temperature.

What is claimed is:

1. A cooler with two-way air convection functionality, having a base, an upper cover and a fan, wherein said upper cover is fastened to said base to form an opening on either side of said base with said fan is placed within, characterized in that:
there is a blocking board at said openings formed by said base and said upper cover, on either side of said fan; said blocking boards diverges air inside said base into two streams, with one stream inhaled from said opening and the other exhausted from the other opening through said rotating fan.

2. The cooler with two-way air convection functionality of claim 1, wherein said cooler can be placed above a motherboard's CPU that is usually placed nearby said motherboard's shell for air convection.

3. A cooler with two-way air convection functionality, having a base, an upper cover and a fan, wherein said upper cover is fastened to said base to form an opening on either side of said base with said fan is placed within, characterized in that:
there is an air guide path inside said base and said upper cover; said guide path can reduces space for air convection and enhances amount of air inhaled and exhausted, thus dissipates heat within.

4. The cooler with two-way air convection functionality of claim 3, wherein said cooler can be placed above a motherboard's CPU that is usually placed nearby said motherboard's shell for air convection.
